(19) United States
(12) Patent Application Publication
(10) Pub. No.: US 2026/0023319 A1
(43) Pub. Date: Jan. 22, 2026

(54) IMAGING MASK STACKS AND METHODS FOR LITHOGRAPHICALLY PATTERNING A SUBSTRATE

(71) Applicant: Tokyo Electron Limited, Tokyo (JP)

(72) Inventors: Lior Huli, Albany, NY (US); Kandabara Tapily, Albany, NY (US); Takahiro Miyahara, Albany, NY (US)

(21) Appl. No.: 19/211,394

(22) Filed: May 19, 2025

Related U.S. Application Data
(60) Provisional application No. 63/674,208, filed on Jul. 22, 2024.

(51) Int. Cl. G03F 7/004; G03F 7/00; G03F 7/20; H01L 21/027

(52) U.S. Cl. CPC G03F 7/0043; G03F 7/0035; G03F 7/2004; G03F 7/70033; G03F 7/70991; H01L 21/0274

(57) ABSTRACT

The present disclosure provides various embodiments of imaging mask stacks, platforms for producing an imaging mask stack, and methods for lithographically patterning a substrate using an imaging mask stack, as described herein. An imaging mask stack in accordance with the present disclosure includes a relatively thin (e.g., 5 nm or less) photosensitive imaging layer formed on or above a thicker mask layer having a significantly higher etch selectivity (e.g., 1:10 or more) than the photosensitive imaging layer. In some embodiments, the imaging mask stack may include one or more additional thin film layers, such as a second photosensitive imaging layer and/or a sensitivity enhancement layer, which enhances absorption of electromagnetic radiation within the photosensitive imaging layer.

### RELATED APPLICATION

This application claims priority to U.S. Provisional Patent Application Ser. No. 63/674,208, which is entitled “Imageable Transfer Layer,” filed on Jul. 22, 2024, and incorporated herein by reference.

### FIELD OF INVENTION

This disclosure relates to the field of semiconductor manufacturing and semiconductor devices, and more particularly, to a method of using an imaging mask stack for lithographically patterning a substrate.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

A common patterning method is to use a photolithography process to expose a coating of photoresist over the target layer to a pattern of actinic radiation and then transfer the relief pattern to the target layer or an underlying hard mask layer formed over the target layer. With this technique, the minimum feature size would be limited by the resolution of the optical system. Scaling of feature sizes for advanced technology nodes is driving lithography to improve resolution. For sub-10 nm technology nodes (for example, 7 nm and 5 nm nodes), 13.5 nm extreme ultraviolet (EUV) lithography is commonly used to pattern a photo resistive film with EUV radiation.

EUV lithography techniques offer significant advantages in patterning sub-10 nm features with its high optical resolution. However, one major engineering challenge for EUV lithography is that photoresists developed for conventional photolithography systems may not satisfy the cost and/or quality requirements for patterning sub-10 nm features. For example, chemically amplified resist (CAR) or similar polymer resists, which are commonly used in 193 nm lithography, are typically produced using liquid based spin-on techniques that consume a significant amount of complex metal cluster precursors, resulting in very high cost. CARs also tend to have low absorption coefficients at 13.5 nm, and thus, may suffer poor sensitivity. Further, the diffusion of photo-activated species in CARs may cause blurring and increase line-edge roughness (LER) in the subsequently formed pattern.

Challenges remain with patterning underlayers using conventional photoresists typically utilized for EUV lithography. When relatively thin photoresist films (having a film thickness <15 nm) are used to form low aspect ratio photoresist patterns, the etch process used to transfer the photoresist pattern to the underlayer(s) may damage the photoresist pattern by significantly etching (or completely removing) portions of the thin photoresist film. In some cases, photoresist damage may be alleviated by depositing a substantially thicker photoresist film (having a film thickness >20 nm) on the underlayer(s) to form a higher aspect ratio photoresist pattern. However, patterning thick photoresist films has its own challenges, oftentimes resulting in photoresist line or pillar collapse.

Accordingly, a need remains for improved photoresists and methods of forming such resists.

### SUMMARY

The present disclosure provides improved photoresists and methods of forming such resists. More specifically, the present disclosure provides various embodiments of imaging mask stacks comprising a relatively thin (e.g., 5 nm or less) photosensitive imaging layer formed on or above a thicker (e.g., 10 nm to 50 nm or more) mask layer. In addition, the present disclosure provides platforms for producing an imaging mask stack, and methods for lithographically patterning a substrate using an imaging mask stack, as described herein.

The photosensitive imaging layer described herein can be formed from a wide variety of photoresist materials that change material properties upon absorption of electromagnetic radiation. The mask layer underlying the photosensitive imaging layer is not photosensitive. The mask layer may generally comprise a metal-containing material or a non-metal material having a significantly higher etch selectivity (e.g., 1:10 or more) than the photosensitive imaging layer. This high etch selectivity enables the mask layer to be etched much faster than the photosensitive imagining layer when the imaging mask stack is subsequently etched to transfer a pattern through the imaging mask stack. In some embodiments, the imaging mask stack may include one or more additional thin film layers, such as a second photosensitive imaging layer and/or a sensitivity enhancement layer, which enhances absorption of the electromagnetic radiation within the photosensitive imaging layer.

The imaging mask stack disclosed herein provides several advantages over conventional photoresist films. First, the thin photosensitive imaging layer (e.g., 5 nm or less) included within the imaging mask stack provides a more uniform and/or homogeneous photoresist film compared to conventional photoresist films, which are typically much thicker (e.g., 20 nm or more) films. By utilizing a thin photosensitive imaging layer within the imaging mask stack, the lithography methods disclosed herein may increase throughput, prevent pattern collapse during a subsequently performed development process and reduce stochastic defects, such as microbridging (MB) and line edge roughness (LER), for example.

According to one embodiment, an imaging mask stack for lithographically patterning a substrate is provided herein. The imaging mask stack may generally include a mask layer formed on one or more underlying layers formed on the substrate, and a photosensitive imaging layer formed on or above the mask layer. The photosensitive imaging layer is generally formed of a photoresist material that absorbs electromagnetic radiation when the substrate is exposed to light. On the other hand, the mask layer is a non-photosensitive layer, which may be formed of a metal-containing material or a non-metal material (such as, for example, a carbon-containing material, a silicon-containing material, an oxide-containing material, a nitride-containing material or a combination thereof). The photosensitive imaging layer is generally a much thinner than the mask layer. For example, the thickness of the photosensitive imaging layer may be 5 nm or less, while the thickness of the mask layer may range between 10 nm to 50 nm (or more).

The photosensitive imaging layer included within the imaging mask stack may be formed from a wide variety of photoresist materials. In one embodiment, the photosensitive imaging layer may include a positive tone development photoresist or a negative tone development photoresist. In another embodiment, the photosensitive imaging layer may include a deep ultra-violet (DUV) photoresist, an extreme ultra-violet (EUV) photoresist, or a high-numerical aperture (NA) EUV photoresist. In yet another embodiment, the photosensitive imaging layer may include a wide variety of metals and metal alloys, such as but not limited to, tin (Sn), antimony (Sb), indium (In), zinc (Zn) and alloys thereof. In further embodiments, the photosensitive imaging layer is doped with a material that differs from a material composition of the photosensitive imaging layer.

The photosensitive imaging layer may also be formed using a wide variety of deposition processes. In one embodiment, the photosensitive imaging layer may be formed using a gas-phase deposition process, a vapor-phase deposition process, or a liquid-phase deposition process. More specifically, the photosensitive imaging layer may be formed using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof.

In some embodiments, the imaging mask stack may include one or more additional thin film layers. In one embodiment, the imaging mask stack may further include a second mask layer formed on the photosensitive imaging layer, and a second photosensitive imaging layer formed on the second mask layer. In such an embodiment, the second mask layer and the second photosensitive imaging layer may each have a thickness of 5 nm or less. The photosensitive imaging layer and the second photosensitive imaging layer may each be formed of a photoresist material. The photoresist material used to form the photosensitive imaging layers may be the same, in some embodiments, and different in other embodiments. Like the mask layer, the second mask layer is a non-photosensitive layer comprising a metal-containing material or a non-metal material. However, unlike the mask layer, the second mask layer may be thin enough (e.g., 5 nm or less) to allow the electromagnetic radiation to pass through the second mask layer to the photosensitive imaging layer underlying the second mask layer.

In another embodiment, the imaging mask stack may further include a sensitivity enhancement layer formed between the mask layer and the photosensitive imaging layer. The sensitivity enhancement layer may be formed of a material that increases absorption of the electromagnetic radiation within the photosensitive imaging layer. For example, the sensitivity enhancement layer may comprise a material with high electron emission (and/or low work function), which increases the amount of photons absorbed by the photosensitive imaging layer. Alternatively, the sensitivity enhancement layer may comprise a material with high diffusion, which allows dopants or impurities to diffuse into the photosensitive imaging layer to increase the absorption of the electromagnetic radiation in the photosensitive imaging layer. In some embodiments, the sensitivity enhancement layer may include a wide variety of metals and metal alloys, such as but not limited to, titanium (Ti), hafnium (Hf), zinc (Zn), another transition metal or alloys thereof.

According to another embodiment, a method for lithographically patterning a substrate is provided herein. The method may generally begin by forming an imaging mask stack on one or more underlying layers formed on the substrate. In general, the imaging mask stack may be formed by depositing a mask layer on the one or more underlying layers, and depositing a photosensitive imaging layer on or above the mask layer. As noted above, the photosensitive imaging layer is generally much thinner than the mask layer. For example, the thickness of the photosensitive imaging layer may be 5 nm or less, while the thickness of the mask layer ranges between 10 nm to 50 nm (or more). The photoresist layer is generally formed of a photoresist material that absorbs electromagnetic radiation when the substrate is exposed to light. On the other hand, the mask layer is a non-photosensitive layer, which may be formed of a metal-containing material or a non-metal material (such as, for example, a carbon-containing material, a silicon-containing material, an oxide-containing material, a nitride-containing material or a combination thereof).

The method may further include: (a) exposing the imaging mask stack to electromagnetic radiation, which is absorbed by exposed portions of the photosensitive imaging layer, wherein the electromagnetic radiation comprises deep ultra-violet (DUV) or extreme ultra-violet (EUV) light, and wherein absorption of the electromagnetic radiation changes a material property of the exposed portions of the photosensitive imaging layer; (b) developing the photosensitive imaging layer, after said exposing the photosensitive imaging layer to electromagnetic radiation, to form a pattern in the photosensitive imaging layer; and (c) performing a first etch process to transfer the pattern formed within the photosensitive imaging layer to the mask layer. During the first etch process, an etch selectivity between the photosensitive imaging layer and the mask layer may be at least 1:10. In one embodiment, the etch selectivity between the photosensitive imaging layer and the mask layer may be 1:50 (or more). This ensures that the mask layer is etched at a much faster rate than the thin photosensitive imaging layer.

As noted above, the photosensitive imaging layer included within the imaging mask stack may be formed from a wide variety of photoresist materials. In one embodiment, for example, the photosensitive imaging layer may include a DUV photoresist, an EUV photoresist, or a high-NA EUV photoresist. In another embodiment, the photosensitive imaging layer may include a wide variety of metals and metal alloys, such as but not limited to, tin (Sn), antimony (Sb), indium (In), zinc (Zn) and alloys thereof. In further embodiments, the method may further comprise doping the photosensitive imaging layer with a material that differs from a material composition of the photosensitive imaging layer. For example, said doping may include plasma immersion doping, ion implant doping, or gas cluster ion implant doping.

A wide variety of deposition processes can be used to deposit the photosensitive imaging layer on or above the mask layer. In one embodiment, the photosensitive imaging layer may be deposited using a gas-phase deposition process, a vapor-phase deposition process, or a liquid-phase deposition process. More specifically, the photosensitive imaging layer may be deposited using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof.

In some embodiments, the imaging mask stack may include one or more additional thin film layers. In one embodiment, said forming the imaging mask stack may further include depositing a second mask layer on the photosensitive imaging layer and depositing a second photosensitive imaging layer on the second mask layer. In such an embodiment, the second mask layer and the second photosensitive imaging layer may each have a thickness of 5 nm or less. The second photosensitive imaging layer may be formed of a photoresist material. The photoresist material used to form the photosensitive imaging layers may be the same, in some embodiments, and different in other embodiments. Like the mask layer, the second mask layer is a non-photosensitive layer comprising a metal-containing material or a non-metal material. However, unlike the mask layer, the second mask layer may be thin enough (e.g., 5 nm or less) to allow the electromagnetic radiation to pass through the second mask layer to the photosensitive imaging layer underlying the second mask layer.

In another embodiment, said forming the imaging mask stack may further include forming a sensitivity enhancement layer between the mask layer and the photosensitive imaging layer. The sensitivity enhancement layer may include a material that increases absorption of the electromagnetic radiation within the photosensitive imaging layer. For example, the sensitivity enhancement layer may comprise a material with high electron emission (and/or low work function), which increases the amount of photons absorbed by the photosensitive imaging layer. Alternatively, the sensitivity enhancement layer may comprise a material with high diffusion, which allows dopants or impurities to diffuse into the photosensitive imaging layer to increase the absorption of the electromagnetic radiation in the photosensitive imaging layer. In some embodiments, the sensitivity enhancement layer may include a wide variety of metals and metal alloys, such as but not limited to, titanium (Ti), hafnium (Hf), zinc (Zn), another transition metal or alloys thereof.

In some embodiments of the method, said forming the imaging mask stack, said developing the photosensitive imaging layer and said performing the first etch process may be performed on a platform comprising a plurality of process modules. The plurality of modules may generally include: (a) a module for depositing the mask layer on one or more underlying layers formed on the substrate, (b) a module for depositing the photosensitive imaging layer on or above the mask layer, (c) a development module for developing the photosensitive imaging layer, after the photosensitive imaging layer is exposed to the electromagnetic radiation, to form the pattern in the photosensitive imaging layer, (d) an etch module for performing the first etch process to transfer the pattern formed within the photosensitive imaging layer to the mask layer, and (e) a transfer module for moving the substrate to one or more of the modules hosted on the platform. In some embodiments, the plurality of modules may further include: (f) one or more treatment modules for pre-treating the substrate prior to forming the photosensitive imaging layer, or post-treating the substrate following the formation of the photosensitive imagining layer, or both.

In some embodiments, said depositing the photosensitive imaging layer and said depositing the mask layer may each be performed on the platform in a chemical vapor deposition (CVD) module. In some embodiments, said depositing the photosensitive imaging layer and said depositing the mask layer may be performed on the platform in the same process module.

In some embodiments, said developing the photosensitive imaging layer may be performed on the platform in the development module using a wet development process, a dry development process, or a combination of a wet and dry development process. For example, the photosensitive imaging layer may be developed using a plasma-free gas-phase development process, a plasma-free vapor-phase development process, a plasma development process, a liquid-phase development process, or any combination of two or more thereof.

In some embodiments, said performing the first etch process may be performed on the platform in the etch module using a wet etch process or a dry etch process. For example, the first etch process may be a plasma-free gas-phase etch process, a plasma-free vapor-phase etch process, a plasma etch process, a liquid-phase etch process, or any combination of two or more thereof. In one example embodiment, the first etch process may be a dry reactive ion etching (RIE) process.

According to another embodiment, a platform is provide for producing an imaging mask stack for lithographically patterning a substrate. The platform may include a plurality of process modules. For example, the platform may generally include a first deposition module configured to deposit a mask layer on one or more underlying layers formed on the substrate and a second deposition module configured to deposit a photosensitive imaging layer on or above the mask layer. As noted above, the photosensitive imaging layer is generally much thinner than the mask layer. For example, a thickness of the mask layer may range between 10 nm to 50 nm (or more), while the thickness of the photosensitive imaging layer is 5 nm or less. The photoresist layer is generally formed of a photoresist material that absorbs electromagnetic radiation when the substrate is exposed to light. On the other hand, the mask layer is a non-photosensitive layer, which may be formed of a metal-containing material or a non-metal material (such as, for example, a carbon-containing material, a silicon-containing material, an oxide-containing material, a nitride-containing material or a combination thereof).

The photosensitive imaging layer deposited by the second deposition module may include a wide variety of photoresist materials. In one embodiment, for example, the photosensitive imaging layer may include a positive tone development photoresist or a negative tone development photoresist. In another embodiment, the photosensitive imaging layer may include a DUV photoresist, an EUV photoresist, or a high-NA EUV photoresist. In yet another embodiment, the photosensitive imaging layer may include a wide variety of metals and metal alloys, such as but not limited to, tin (Sn), antimony (Sb), indium (In), zinc (Zn) and alloys thereof. In further embodiments, the photosensitive imaging layer may be doped with a material that differs from a material composition of the photosensitive imaging layer.

The first deposition module and the second deposition module may each utilize a gas-phase deposition process, a vapor-phase deposition process, or a liquid-phase deposition process to deposit the mask layer and the photosensitive imaging layer. For example, the first deposition module and the second deposition module may utilize a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof to deposit the mask layer and the photosensitive imaging layer. In one example embodiment, the first deposition module and the second deposition module may utilize a chemical vapor deposition (CVD) process to deposit the mask layer and the photosensitive imaging layer. In some embodiments, the first deposition module and the second deposition module may be the same module.

In some embodiments, the first deposition module may be further configured to deposit a second mask layer on the photosensitive imaging layer. Like the first mask layer, the second mask layer is a non-photosensitive layer, which may include a metal-containing material or a non-metal material, and may be deposited to a thickness of 5 nm or less.

In some embodiments, the second deposition module may be further configured to deposit a second photosensitive imaging layer on the second mask layer. Like the photosensitive imaging layer, the second photosensitive imaging layer may include the photoresist material, and may be deposited to a thickness of 5 nm or less.

In some embodiments, the platform may include one or more additional process modules. In one embodiment, for example, the platform may include a third deposition module, which is configured to deposit a sensitivity enhancement layer between the mask layer and the photosensitive imaging layer. The sensitivity enhancement layer may generally include a material that increases absorption of the electromagnetic radiation within the photosensitive imaging layer. For example, the sensitivity enhancement layer may comprise a material with high electron emission (and/or low work function), which increases the amount of photons absorbed by the photosensitive imaging layer. Alternatively, the sensitivity enhancement layer may comprise a material with high diffusion, which allows dopants or impurities to diffuse into the photosensitive imaging layer to increase the absorption of the electromagnetic radiation in the photosensitive imaging layer. In some embodiments, the sensitivity enhancement layer may include a wide variety of metals and metal alloys, such as but not limited to, titanium (Ti), hafnium (Hf), zinc (Zn), another transition metal or alloys thereof.

The third deposition module may utilize a gas-phase deposition process, a vapor-phase deposition process, or a liquid-phase deposition process to deposit the mask layer and the photosensitive imaging layer. For example, the third deposition module may utilize a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof to deposit the sensitivity enhancement layer. In one example embodiment, the third deposition module may utilize a chemical vapor deposition (CVD) process to deposit the sensitivity enhancement layer.

In some embodiments, the platform may further include: (a) a development module configured to develop the photosensitive imaging layer, after the photosensitive imaging layer is exposed to the electromagnetic radiation, to form a pattern in the photosensitive imaging layer; (b) an etch module configured to perform a first etch process to transfer the pattern formed within the photosensitive imaging layer to the mask layer; and (d) a transfer module configured to move the substrate to one or more modules hosted on the platform. In sone embodiments, the platform may further include: (e) one or more treatment modules configured to pre-treat the substrate prior to forming the photosensitive imaging layer, or post-treat the substrate following the formation of the photosensitive imagining layer, or both. In some embodiments, the platform may be coupled to an exposure platform, which is configured to expose the substrate to the electromagnetic radiation. In such embodiments, a transfer module may be coupled between the platform and the exposure platform to move the substrate there between.

In some embodiments, the development module may be a wet development module or a dry development module. For example, the development module may utilize a plasma-free gas-phase development process, a plasma-free vapor-phase development process, a plasma development process, a liquid-phase development process, or any combination of two or more thereof to develop the photosensitive imaging layer.

In some embodiments, the etch module may be a wet etch module or a dry etch module. For example, the etch module may utilize a plasma-free gas-phase etch process, a plasma-free vapor-phase etch process, a plasma etch process, a liquid-phase etch process, or any combination of two or more thereof to transfer the pattern formed within the photosensitive imaging layer to the mask layer. In one example embodiment, the etch module may utilize dry reactive ion etching (RIE) to transfer the pattern formed within the photosensitive imaging layer to the mask layer.

As noted above and described further herein, the present disclosure provides various embodiments of various embodiments of imaging mask stacks, platforms for producing an imaging mask stack, and methods for lithographically patterning a substrate using an imaging mask stack as described herein. Of course, the order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this Summary Section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1D illustrate a process flow for forming an imaging mask stack in accordance with one embodiment of the present disclosure.

FIGS. 1E-1H illustrate an example process flow for lithographically patterning a substrate using an imaging mask stack, as disclosed herein.

FIGS. 2A-2H illustrate a process flow for forming an imaging mask stack in accordance with another embodiment of the present disclosure.

FIGS. 3A-3E illustrate a process flow for forming an imaging mask stack in accordance with another embodiment of the present disclosure.

FIG. 4 is a block diagram illustrating one embodiment of a platform that utilizes the techniques described herein.

FIG. 5 is a block diagram illustrating one embodiment of an exposure tool integrated with the platform shown in FIG. 4.

FIG. 6 is flowchart diagram illustrating one embodiment of a method that utilizes the techniques described herein for lithographically patterning a substrate.

### DETAILED DESCRIPTION

The present disclosure provides improved photoresists and methods of forming such resists. More specifically, the present disclosure provides various embodiments of imaging mask stacks comprising a relatively thin (e.g., 5 nm or less) photosensitive imaging layer formed on or above a thicker (e.g., 10 nm to 50 nm or more) mask layer. In addition, the present disclosure provides platforms for producing an imaging mask stack, and methods for lithographically patterning a substrate using an imaging mask stack, as described herein.

The photosensitive imaging layer described herein can be formed from a wide variety of photoresist materials that change material properties upon absorption of electromagnetic radiation. The mask layer underlying the photosensitive imaging layer is not photosensitive. The mask layer may generally comprise a metal-containing material or a non-metal material having a significantly higher etch selectivity (e.g., 1:10 or more) than the photosensitive imaging layer. This high etch selectivity enables the mask layer to be etched much faster than the photosensitive imagining layer when the imaging mask stack is subsequently etched to transfer a pattern through the imaging mask stack. In some embodiments, the imaging mask stack may include one or more additional thin film layers, such as a second photosensitive imaging layer and/or a sensitivity enhancement layer, which enhances absorption of the electromagnetic radiation within the photosensitive imaging layer.

The imaging mask stack disclosed herein provides several advantages over conventional photoresist films. First, the thin photosensitive imaging layer (e.g., 5 nm or less) included within the imaging mask stack provides a more uniform and/or homogeneous photoresist film compared to conventional photoresist films, which are typically much thicker (e.g., 20 nm or more) films. By utilizing a thin photosensitive imaging layer within the imaging mask stack, the lithography methods disclosed herein may increase throughput, prevent pattern collapse during a subsequently performed development process and reduce stochastic defects, such as microbridging (MB) and line edge roughness (LER), for example.

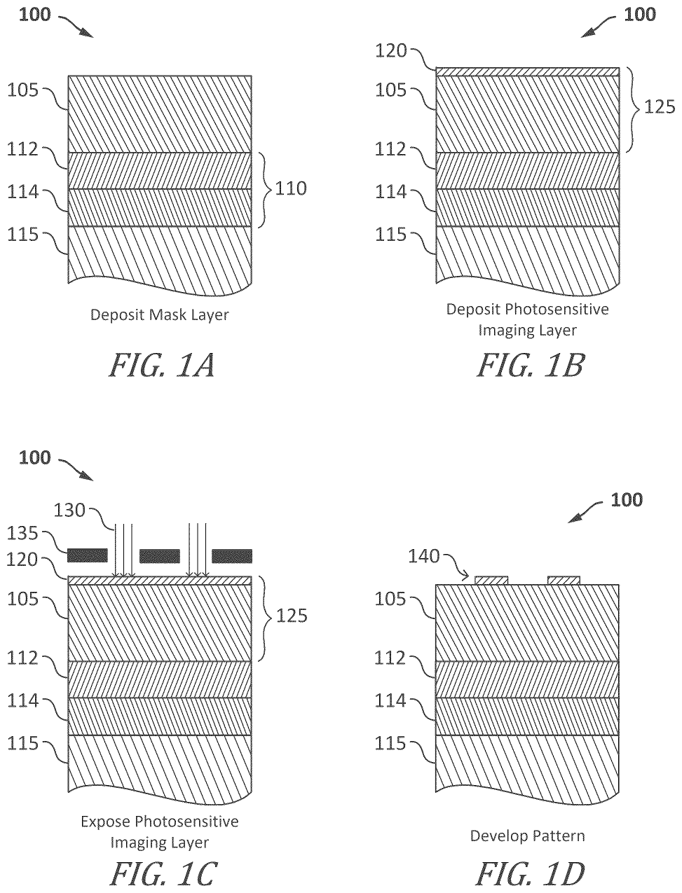

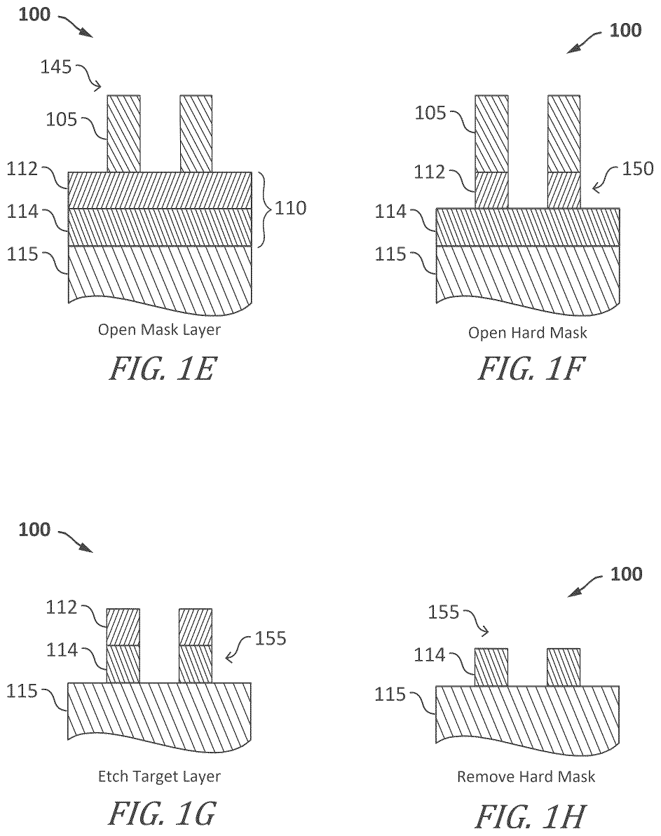

Turning now to the Drawings, FIGS. 1A-1D depict a process flow 100 that can be used to form an imaging mask stack, in accordance with one embodiment of the present disclosure. An imaging mask stack 125 is formed in FIGS. 1A-1B by depositing a mask layer 105 on one or more underlying layers 110 formed on a substrate 115 (in FIG. 1A), and subsequently depositing a photosensitive imaging layer 120 on or above the mask layer 105 (in FIG. 1B). The substrate 115 may be a semiconductor substrate (e.g., a silicon substrate, a silicon-on-insulator (“SOI”) substrate, etc.). In one embodiment, the one or more underlying layers 110 formed on the substrate 115 may include a hard mask 112 and a target layer 114 to be etched using the layers above the target layer 114 as an etching mask. The hard mask 112 may include a wide variety of hard mask materials. In one embodiment, the hard mask 112 may include a silicon-containing material such as, for example, silicon dioxide (SiO₂) or silicon nitride (SiN). The target layer 114 to be etched may also include a wide variety of material layers for which etching is desirable.

The photosensitive imaging layer 120 is generally formed of a photoresist material that absorbs electromagnetic radiation when the substrate is exposed to light. On the other hand, the mask layer 105 may be non-photosensitive layer formed of a metal-containing material or a non-metal material (such as, for example, a carbon-containing material, a silicon-containing material, an oxide-containing material, a nitride-containing material or a combination thereof). The photosensitive imaging layer 120 is generally much thinner than the mask layer 105. For example, the thickness of the photosensitive imaging layer 120 may be 5 nm or less, while the thickness of the mask layer 105 may range between 10 nm to 50 nm (or more).

The photosensitive imaging layer 120 included within the imaging mask stack 125 may be formed from a wide variety of photoresist materials. As known in the art, photoresist materials change material properties upon absorption of electromagnetic radiation, rendering them more (or less) soluble to developer solutions. There are generally two types of photoresists: positive tone development photoresists which become more soluble in a developer solution when exposed to light, and negative tone development photoresists which become less soluble (or even insoluble) in a developer solution when exposed to light. In some embodiments, the photosensitive imaging layer 120 may be a positive tone development photoresist. In other embodiments, the photosensitive imaging layer 120 may be a negative tone development photoresist.

In one example embodiment, the photosensitive imaging layer 120 may include a deep ultra-violet (DUV) photoresist, an extreme ultra-violet (EUV) photoresist, or a high-numerical aperture (NA) EUV photoresist. In another example embodiment, the photosensitive imaging layer 120 may include a metal and metal alloy, such as but not limited to, tin (Sn), antimony (Sb), indium (In), zinc (Zn) and alloys thereof. In some embodiments, the photosensitive imaging layer 120 may be doped with a material that differs from a material composition of the photosensitive imaging layer. For example, the photosensitive imaging layer 120 may doped with various metals (such as, Sn, Sb, In, Zn, etc.) or non-metals (such as, boron (B), phosphorus (P), etc.) using plasma immersion doping, ion implant doping, or gas cluster ion implant doping.

The mask layer 105 underlying the photosensitive imaging layer 120 is not a photosensitive layer, and thus, does not change material properties upon exposure to electromagnetic radiation. In some embodiments, the mask layer 105 may comprise a metal-containing material. In other embodiments, the mask layer 105 may comprise a non-metal material, such as a carbon-containing material, a silicon-containing material, an oxide-containing material, a nitride-containing material or a combination thereof. In either embodiment, the mask layer 105 is comprised of a material that exhibits high etch selectivity with respect to the photosensitive imaging layer 120 to enable high selectivity transfer of a pattern through the imaging mask stack 125. In some embodiments, the etch selectivity between the photosensitive imaging layer 120 and the mask layer 105 may be at least 1:10. In one example, the etch selectivity between the photosensitive imaging layer 120 and the mask layer 105 may be 1:50 (or more). The mask layer 105 can include a wide variety of carbon-containing, silicon-containing, oxide-containing and/or nitride-containing materials. In one embodiment, the mask layer 105 may include carbon (e.g., an amorphous carbon layer (ACL)) or silicon. In another embodiment, the mask layer 105 may include a combination of the materials listed above (such as, e.g., silicon carbide, SiC)

A wide variety of deposition processes can be used to form the layers included within the imaging mask stack 125. In one embodiment, the mask layer 105 and the photosensitive imaging layer 120 may each be formed using a gas-phase deposition process, a vapor-phase deposition process, or a liquid-phase deposition process. For example, the mask layer 105 and the photosensitive imaging layer 120 may each be formed using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof. In one example embodiment, a CVD process may be used to deposit each of the layers included within the imaging mask stack 125.

After forming the imaging mask stack 125, the process flow 100 may continue in FIG. 1C by exposing the imaging mask stack 125 to electromagnetic radiation 130 through a mask 135 that exposes portions of the photosensitive imaging layer 120. In some embodiments, the electromagnetic radiation 130 may include DUV or EUV light. The exposed portions of the photosensitive imaging layer 120 absorb the electromagnetic radiation 130. Upon absorbing the electromagnetic radiation 130, a material property of the exposed portions of the photosensitive imaging layer 120 is changed, for example, to render the exposed portions more soluble (in the case of a positive tone resist) or less soluble (in the case of a negative tone resist) in a developing solution. Thereafter, a development process is performed to remove the exposed portions (in the case of a positive tone resist) or the unexposed portions (in the case of a negative tone resist) of the photosensitive imaging layer 120 to form a pattern 140 in the photosensitive imaging layer 120. In the example shown in FIG. 1D, the development process removes the unexposed portions of the photosensitive imaging layer 120 from the surface of the mask layer 105 to form the pattern 140 on the mask layer 105.

A wide variety of development processes can be used to develop the photosensitive imaging layer 120 and form the pattern 140 in the photosensitive imaging layer 120. In one embodiment, the photosensitive imaging layer 120 can be developed using a wet development process, a dry development process, or a combination of a wet and dry development process. For example the photosensitive imaging layer 120 can be developed using a plasma-free gas-phase development process, a plasma-free vapor-phase development process, a plasma development process, a liquid-phase development process, or any combination of two or more thereof.

After the pattern 140 is formed in the photosensitive imaging layer 120, the process flow 100 may perform additional steps to transfer the pattern 140 through the mask layer 105, the hard mask 112, and into the target layer 114. For example, the process flow 100 may perform a first etch process to etch (or open) the mask layer 105 using the pattern 140 as an etch mask. As shown in FIG. 1E, the mask layer 105 is etched to remove portions of the mask layer 105 not covered by the pattern 140 to form etch features 145 in the mask layer 105, which can be used to pattern the one or more underlying layers 110 underlying the imaging mask stack 125. A wide variety of etch processes can be used to etch the mask layer 105 in FIG. 1E. For example, the first etch process may be a plasma-free gas-phase etch process, a plasma-free vapor-phase etch process, a plasma etch process, a liquid-phase etch process, or any combination of two or more thereof. In one example embodiment, the first etch process may be a dry reactive ion etching (RIE) process.

During the first etch process, the mask layer 105 exhibits high etch selectivity with respect to the photosensitive imaging layer 120 to enable high selectivity transfer of the pattern 140 through the mask layer. High etch selectivity is provided, not only by the materials used to implement the mask layer 105 and the photosensitive imaging layer 120, but also by the etch process used to selectively etch the mask layer 105. In one example, a dry RIE process may provide an etch selectivity of at least 1:10 between a photosensitive imaging layer 120 comprising a thin (e.g., 5 nm or less) photoresist film and a mask layer 105 comprising amorphous carbon. In some embodiments, any photoresist material remaining on the surface of the mask layer 105 may be removed after the mask layer 105 is opened and the etch features 145 are formed in the mask layer 105. For example, a standard cleaning process may be performed to remove any remaining photoresist material.

After the etch features 145 are formed, the process flow 100 may perform a second etch process to etch (or open) the hard mask 112 to form etch features 150 in the hard mask 112 using the etch features 145 formed in the mask layer 105 as an etch mask. A wide variety of etch processes can be used to etch the hard mask 112 in FIG. IF. For example, the second etch process may be a plasma-free gas-phase etch process, a plasma-free vapor-phase etch process, a plasma etch process, a liquid-phase etch process, or any combination of two or more thereof. In one example embodiment, the second etch process may be a dry reactive ion etching (RIE) process.

After the etch features 150 are formed, the process flow 100 may perform a third etch process to etch (or open) the target layer 114 to form etch features 155 in the target layer 114 using the etch features 150 formed in the hard mask 112 as an etch mask. A wide variety of etch processes can be used to etch the target layer 114 in FIG. 1G. For example, the third etch process may be a plasma-free gas-phase etch process, a plasma-free vapor-phase etch process, a plasma etch process, a liquid-phase etch process, or any combination of two or more thereof. In one example embodiment, the third etch process may be a dry reactive ion etching (RIE) process. Once the target layer 114 is etched, the patterned hard mask 112 may be removed from the surface of the patterned target layer 114 in FIG. 1H using any standard hard mask removal process.

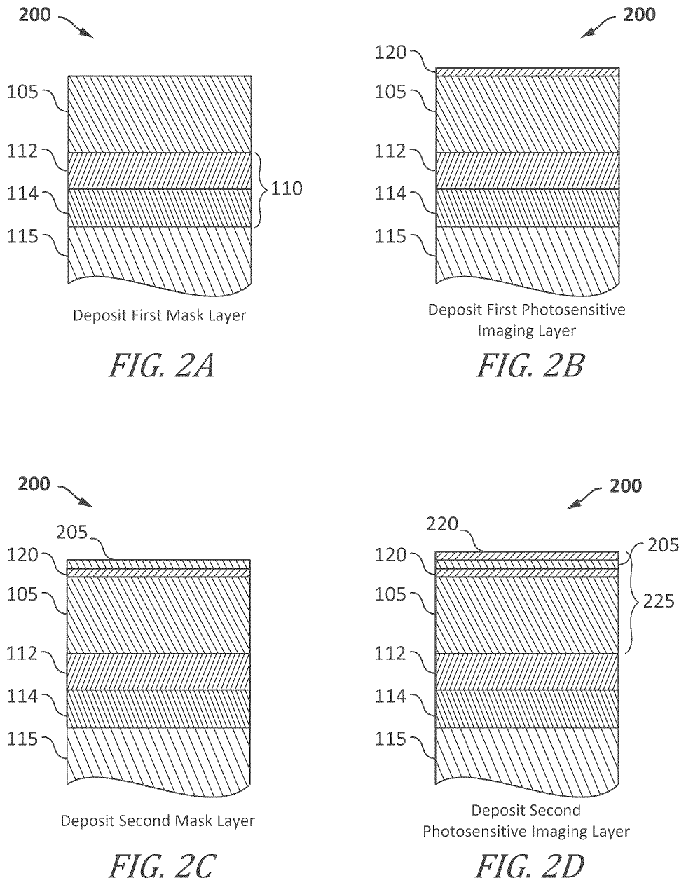

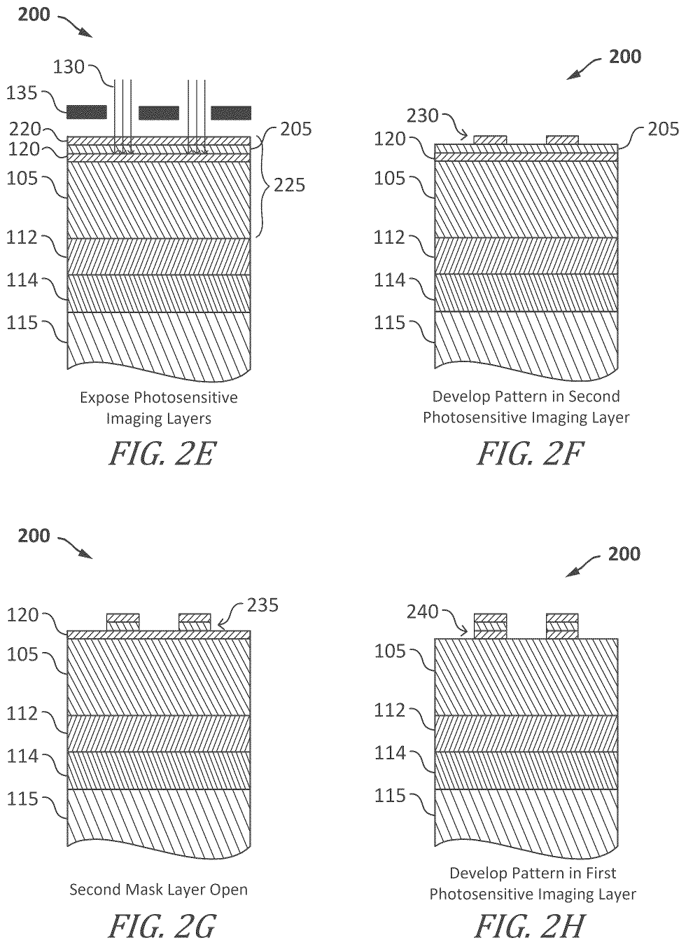

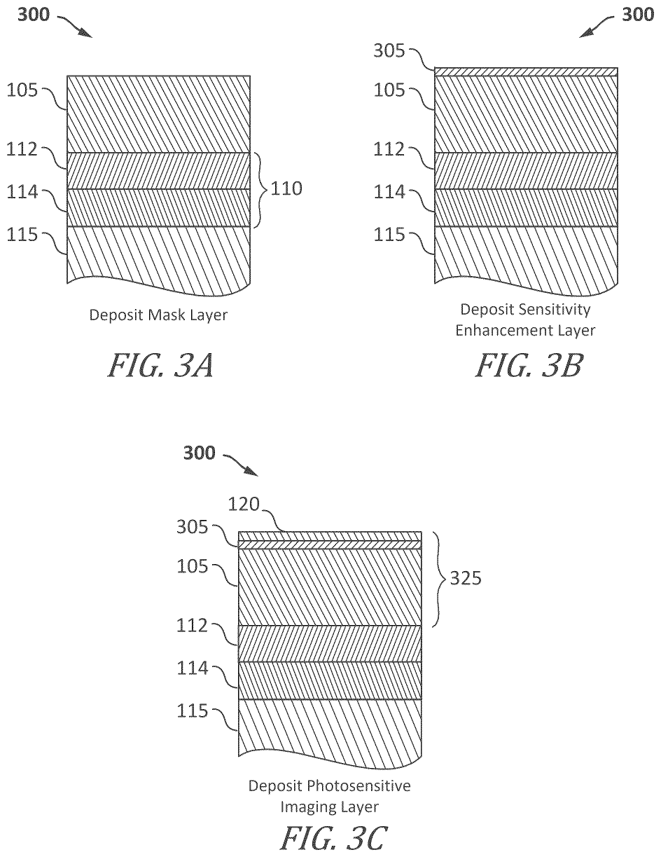

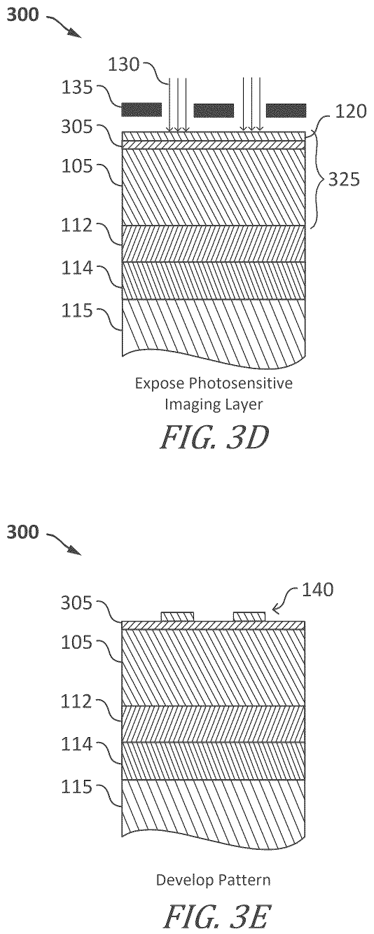

FIGS. 1A-1H illustrate one embodiment of a process flow 100 and patterning method that patterns a thin (e.g., 5 nm or less) photosensitive imaging layer 120 and transfer the pattern 140 formed within the thin photosensitive imaging layer 120 through the mask layer 105, the hard mask 112 and into the target layer 114. The thin photosensitive imaging layer 120 used in the process flow 100 provides a more uniform and/or homogeneous photoresist film compared to conventional photoresist films, which are typically much thicker (e.g., 20 nm or more) films. The thin photosensitive imaging layer 120 may also increase throughput, prevent pattern collapse during the development process (FIG. 1D) and reduce stochastic defects such as, for example, microbridging (MB) and line edge roughness (LER) in the resulting patterned structure. While acceptable etch results can be achieved using the process flow 100 shown in FIGS. 1A-1H, additional thin films can be added to the imaging mask stack 125 to improve sensitivity and resist scumming at the bottom of the patterned structure. For example, a second photosensitive imaging layer and/or a sensitivity enhancement layer can be added to the imaging mask stack 125 as shown in FIGS. 2A-2H and FIGS. 3A-3E.

FIGS. 2A-2H depict a process flow 200 that can be used to form an imaging mask stack, in accordance with another embodiment of the present disclosure. The process flow 200 shown in FIGS. 2A-2H is similar to the process flow 100 shown in FIGS. 1A-1D in that it begins by depositing a mask layer 105 on one or more underlying layers 110 formed on a substrate 115 (in FIG. 2A), and subsequently deposits a photosensitive imaging layer 120 on or above the mask layer 105 (in FIG. 2B). The mask layer 105, the underlying layers 110, the substrate 115 and the photosensitive imaging layer 120 are equivalent to those described above.

The process flow 200 differs from the process flow 100 by depositing a second mask layer 205 on the photosensitive imaging layer 120 (in FIG. 2C), and subsequently depositing a second photosensitive imaging layer 220 on the second mask layer 205 (in FIG. 2D) to form the imaging mask stack 225. In the embodiment shown in FIGS. 2A-2D, the second mask layer 205 and the second photosensitive imaging layer 220 are thin film layers, each having a thickness of 5 nm or less. Like the photosensitive imaging layer 120, the second photosensitive imaging layer 220 may generally be formed of a photoresist material. Examples of photoresist materials are discussed above. The photoresist material used to form the photosensitive imaging layers 120 and 220 may be the same, in some embodiments, and different in other embodiments. Like the mask layer 105, the second mask layer 205 is a non-photosensitive layer, which may generally comprise a metal-containing material or a non-metal material that exhibits high etch selectivity with respect to the photosensitive imaging layers 120 and 220. Examples of suitable materials for the mask layers 105 and 205 are provided above. Unlike the mask layer 105, the second mask layer 205 must be thin enough (e.g., 5 nm or less) to allow electromagnetic radiation 130 to pass through the second mask layer 205 to the photosensitive imaging layer 120 underlying the second mask layer 205.

A wide variety of deposition processes can be used to form the layers included within the imaging mask stack 225. In one embodiment, the mask layer 105, the photosensitive imaging layer 120, the second mask layer 205 and the second photosensitive imaging layer 220 may each be formed using a gas-phase deposition process, a vapor-phase deposition process, or a liquid-phase deposition process. For example, the mask layer 105, the photosensitive imaging layer 120, the second mask layer 205 and the second photosensitive imaging layer 220 may each be formed using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof. In one example embodiment, a CVD process may be used to deposit each of the layers included within the imaging mask stack 225.

After forming the imaging mask stack 225, the process flow 200 may continue in FIG. 2E by exposing the imaging mask stack 225 to electromagnetic radiation 130 through a mask 135 that exposes portions of the photosensitive imaging layer 120 and portions of the second photosensitive imaging layer 220. In some embodiments, the electromagnetic radiation 130 may include DUV or EUV light. In this embodiment, the DUV or EUV light is transmitted through the second mask layer 205 formed between the second photosensitive imaging layer 220 and the (first) photosensitive imagining layer 120. The exposed portions of the photosensitive imaging layers 120 and 220 absorb the electromagnetic radiation 130. Upon absorbing the electromagnetic radiation 130, a material property of the exposed portions of the photosensitive imaging layers 120 and 220 is changed, for example, to render the exposed portions more soluble (in the case of a positive tone resist) or less soluble (in the case of a negative tone resist) in a developing solution.

Thereafter, a first development process is performed to remove the exposed portions (in the case of a positive tone resist) or the unexposed portions (in the case of a negative tone resist) of the second photosensitive imaging layer 220 to form a pattern 230 in the second photosensitive imaging layer 220. In the example shown in FIG. 2F, the first development process removes the unexposed portions of the second photosensitive imaging layer 220 from the surface of the second mask layer 205 to form the pattern 230 on the second mask layer 205. A wide variety of development processes may be used to develop the second photosensitive imaging layer 220 and form the pattern 230 in the second photosensitive imaging layer 220, as described above.

After the pattern 230 is formed in the second photosensitive imaging layer 220, an etch process may be performed to etch (or open) the second mask layer 205 using the pattern 230 as an etch mask. As shown in FIG. 2G, the second mask layer 205 is etched to remove portions of the second mask layer 205 not covered by the pattern 230 to form etch features 235 in the second mask layer 205. A wide variety of etch processes can be used to etch the second mask layer 205, as described above.

Thereafter, a second development process is performed to remove the exposed portions (in the case of a positive tone resist) or the unexposed portions (in the case of a negative tone resist) of the photosensitive imaging layer 120 to form a pattern 240 in the photosensitive imaging layer 120. In the example shown in FIG. 2H, the second development process removes the unexposed portions of the photosensitive imaging layer 120 from the surface of the mask layer 105 to form the pattern 240 on the mask layer 105. A wide variety of development processes may be used to develop the photosensitive imaging layer 120 and form the pattern 240 in the photosensitive imaging layer 120, as described above.

After the pattern 240 is formed in the photosensitive imaging layer 120, the process flow 200 may perform additional steps to transfer the pattern 240 through the mask layer 105, the hard mask 112, and into the target layer 114. For example, the process flow 200 may perform: (a) a first etch process to etch (or open) the mask layer 105 using the pattern 240 as an etch mask (as shown in FIG. 1E), (b) a second etch process to etch (or open) the hard mask 112 to form etch features 150 in the hard mask 112 using the etch features 145 formed in the mask layer 105 as an etch mask (as shown in FIG. 1F), and (c) a third etch process to etch (or open) the target layer 114 to form etch features 155 in the target layer 114 using the etch features 150 formed in the hard mask 112 as an etch mask (as shown in FIG. 1G). A wide variety of etch processes can be used to etch the mask layer 105, the hard mask 112 and the target layer 114, as described above. Once the target layer 114 is etched, the patterned hard mask 112 may be removed from the surface of the patterned target layer 114 in FIG. 1H using any standard hard mask removal process.

FIGS. 2A-2H and FIGS. 1E-1H illustrate one embodiment of a process flow 200 and patterning method for patterning at least two thin (e.g., 5 nm or less) photosensitive imaging layers 120 and 220 and thereafter transferring the pattern 240 through the mask layer 105, the hard mask 112 and into the target layer 114. In some embodiments, more than two photosensitive imaging layers can be used within the imaging mask stack 225. The use of two (or more) photosensitive imaging layers can improve imaging sensitivity and reduce scum and the bottom of the stack.

FIGS. 3A-3E depict a process flow 300 that can be used to form an imaging mask stack, in accordance with yet another embodiment of the present disclosure. The process flow 300 shown in 3A-3E is similar to the process flow 100 shown in FIGS. 1A-1D in that it begins by depositing a mask layer 105 on one or more underlying layers 110 formed on a substrate 115 (in FIG. 3A). The mask layer 105, the underlying layers 110 and the substrate 115 are equivalent to those described above.

The process flow 300 differs from the process flow 100 by depositing a sensitivity enhancement layer 305 on the mask layer 105 (in FIG. 3B) before depositing the photosensitive imaging layer 120 on the sensitivity enhancement layer 305 (in FIG. 3C) to form the imaging mask stack 325. In the embodiment shown in FIGS. 3A-3C, the sensitivity enhancement layer 305 and the photosensitive imaging layer 120 are thin film layers, each having a thickness of 5 nm or less. The photosensitive imaging layer 120 may generally be formed of a photoresist material. Examples of photoresist materials are discussed above. The sensitivity enhancement layer 305, on the other hand, may be formed of a material that increases absorption of the electromagnetic radiation 130 within the photosensitive imaging layer 120 during the exposure step shown in FIG. 3D.

A wide variety of materials may be used to form the sensitivity enhancement layer 305. For example, the sensitivity enhancement layer 305 may comprise a material with high electron emission (and/or low work function), which increases the amount of photons absorbed by the photosensitive imaging layer. Alternatively, the sensitivity enhancement layer 305 may comprise a material with high diffusion, which allows dopants or impurities to diffuse into the photosensitive imaging layer to increase the absorption of the electromagnetic radiation in the photosensitive imaging layer. In some embodiments, the sensitivity enhancement layer 305 may include a wide variety of transition metals and transition metal alloys, such as but not limited to, titanium (Ti), hafnium (Hf), zinc (Zn), or alloys thereof.

A wide variety of deposition processes can be used to form the layers included within the imaging mask stack 325. In one embodiment, the mask layer 105, the sensitivity enhancement layer 305 and the photosensitive imaging layer 120 may each be formed using a gas-phase deposition process, a vapor-phase deposition process, or a liquid-phase deposition process. For example, the mask layer 105, the sensitivity enhancement layer 305 and the photosensitive imaging layer 120 may each be formed using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof. In one example embodiment, a CVD process may be used to deposit each of the layers included within the imaging mask stack 325.

After forming the imaging mask stack 325, the process flow 300 may continue in FIG. 3D by exposing the imaging mask stack 325 to electromagnetic radiation 130 through a mask 135 that exposes portions of the photosensitive imaging layer 120. In some embodiments, the electromagnetic radiation 130 may include DUV or EUV light. The exposed portions of the photosensitive imaging layer 120 absorb the electromagnetic radiation 130. Upon absorbing the electromagnetic radiation 130, a material property of the exposed portions of the photosensitive imaging layer 120 is changed, for example, to render the exposed portions more soluble (in the case of a positive tone resist) or less soluble (in the case of a negative tone resist) in a developing solution. Thereafter, a development process is performed to remove the exposed portions (in the case of a positive tone resist) or the unexposed portions (in the case of a negative tone resist) of the photosensitive imaging layer 120 to form a pattern 140 in the photosensitive imaging layer 120. In the example shown in FIG. 3E, the development process removes the unexposed portions of the photosensitive imaging layer 120 from the surface of the sensitivity enhancement layer 305 to form the pattern 140 on the sensitivity enhancement layer 305. A wide variety of development processes may be used to develop the photosensitive imaging layer 120 and form the pattern 140 in the photosensitive imaging layer 120, as described above.

After the pattern 140 is formed in the photosensitive imaging layer 120, the process flow 300 may perform additional steps to transfer the pattern 140 through the sensitivity enhancement layer 305, the mask layer 105, the hard mask 112, and into the target layer 114. For example, the process flow 300 may perform: (a) a first etch process to etch the sensitivity enhancement layer 305 and the mask layer 105 using the pattern 140 as an etch mask (as shown in FIG. 1E), (b) a second etch process to etch the hard mask 112 to form etch features 150 in the hard mask 112 using the etch features 145 formed in the mask layer 105 as an etch mask (as shown in FIG. 1F), and (c) a third etch process to etch the target layer 114 to form etch features 155 in the target layer 114 using the etch features 150 formed in the hard mask 112 as an etch mask (as shown in FIG. 1G). A wide variety of etch processes can be used to etch the sensitivity enhancement layer 305, the mask layer 105, the hard mask 112 and the target layer 114, as described above. Once the target layer 114 is etched, the patterned hard mask 112 may be removed from the surface of the patterned target layer 114 in FIG. 1H using any standard hard mask removal process.

FIGS. 3A-3E and FIGS. 1E-1H illustrate one embodiment of a process flow 300 and patterning method for patterning a thin (e.g., 5 nm or less) photosensitive imaging layer 120 and thereafter transferring the pattern 140 through the sensitivity enhancement layer 305, the mask layer 105, the hard mask 112 and into the target layer 114. The use of the sensitivity enhancement layer 305 in the process flow 300 improves imaging sensitivity by increasing absorption of the electromagnetic radiation 130 within the photosensitive imaging layer 120 during the exposure step shown in FIG. 3D.

The process flow steps shown in FIGS. 1-3 and described above can be performed on a wide variety of substrate processing tools and systems. In some embodiments, the process flow steps may be performed on a platform comprising plurality of process modules.

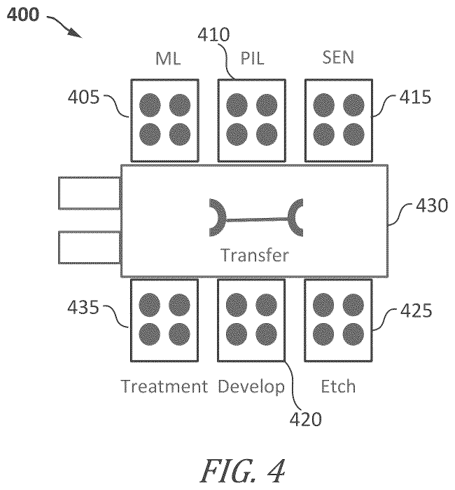

FIG. 4 illustrates one embodiment of a stand-alone platform 400 that can be used to produce an imaging mask stack for lithographically patterning a substrate according to an embodiment of the present disclosure. The platform 400 may include a plurality of process modules. For example, the platform 400 may include: (a) a first deposition module 405 configured to deposit a mask layer (ML) on one or more underlying layers formed on a substrate, (b) a second deposition module 410 configured to deposit at least one photosensitive imaging layer (PIL) on the mask layer, and (c) a third deposition module 415 configured to deposit a sensitivity enhancement layer (SEN) between the mask layer and the photosensitive imaging layer. The mask layer, photosensitive imaging layer and sensitivity enhancement layer may each be formed and configured, as described above in reference to FIGS. 1-3.

The first deposition module 405, the second deposition module 410 and the third deposition module 415 may each utilize a gas-phase deposition process, a vapor-phase deposition process, or a liquid-phase deposition process to deposit the mask layer, the photosensitive imaging layer and the sensitivity enhancement layer. For example, the first deposition module 405, the second deposition module 410 and the third deposition module 415 may utilize a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof to deposit the mask layer and the photosensitive imaging layer. In one example embodiment, first deposition module 405, the second deposition module 410 and the third deposition module 415 module may utilize a chemical vapor deposition (CVD) process to deposit the mask layer, the photosensitive imaging layer and the sensitivity enhancement layer. In some embodiments, the first deposition module 405, the second deposition module 410 and/or the third deposition module 415 may be the same module.

The platform 400 may further include: (a) a development module 420 configured to develop the photosensitive imaging layer, after the photosensitive imaging layer is exposed to the electromagnetic radiation, to form a pattern in the photosensitive imaging layer; (b) an etch module 425 configured to perform one or more etch processes to transfer the pattern formed within the photosensitive imaging layer to the mask layer and the underlying layers; and (d) a transfer module 430 configured to move the substrate between the various process modules hosted on the platform 400. In some embodiments, the platform 400 may further include: (e) one or more treatment modules 435 configured to pre-treat the substrate prior to forming the photosensitive imaging layer, or post-treat the substrate following the formation of the photosensitive imagining layer, or both.

A wide variety of development processes can be performed within the development module 420 to develop the photosensitive imaging layer, after the photosensitive imaging layer is exposed to the electromagnetic radiation, to form a pattern in the photosensitive imaging layer. In some embodiments, the development module 420 may be a wet development module that uses a liquid-phase development process to develop the photosensitive imaging layer. In other embodiments, the development module 420 may be a dry development module that uses a plasma-free gas-phase development process, a plasma-free vapor-phase development process, or a plasma development process to develop the photosensitive imaging layer. Alternatively, the development module 420 can use a combination of wet and dry process steps to develop the photosensitive imaging layer.

Likewise, a wide variety of etch processes can be performed within the etch module 425 to transfer the pattern formed within the photosensitive imaging layer to the mask layer and the underlying layers. In some embodiments, the etch module 425 may be a wet etch module that uses a liquid-phase etch process to etch the mask layer and the underlying layers using the pattern formed within the photosensitive imaging layer as an etch mask. In other embodiments, the etch module 425 may be a dry etch module that uses a plasma-free gas-phase etch process, a plasma-free vapor-phase etch process or a plasma etch process to etch the mask layer and the underlying layers. In one example embodiment, the etch module 425 may utilize dry reactive ion etching (RIE) to etch the mask layer and the underlying layers.

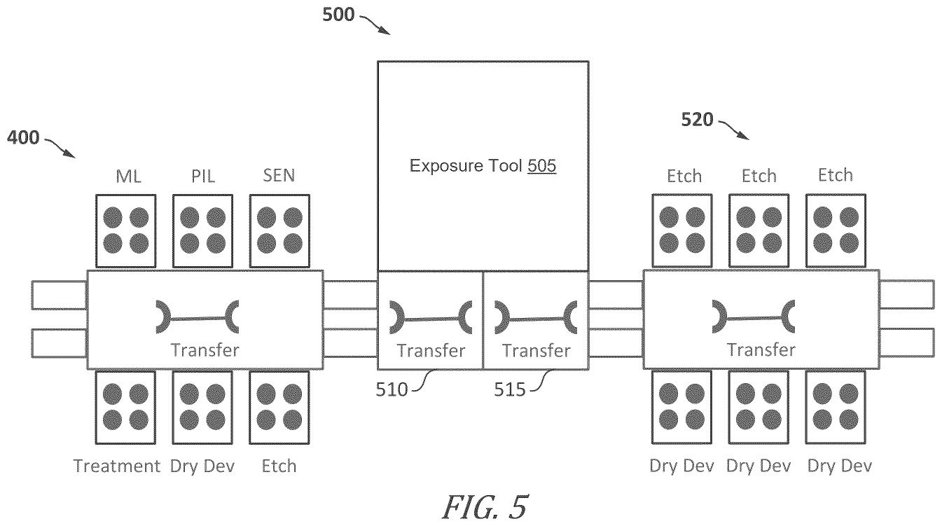

In some embodiments, the platform 400 shown in FIG. 4 may be coupled to one or more additional platforms, forming an integrated platform as shown for example in FIG. 5. In the embodiment shown in FIG. 5, the platform 400 is coupled to an exposure platform 500 that includes an exposure tool 505 configured to expose substrates to electromagnetic radiation. In some embodiments, the exposure tool 505 may be configured to expose substrates to DUV or EUV light. The exposure platform 500 further includes: (a) a first transfer module 510 coupled between the platform 400 and the exposure platform 500 to move the substrates there between, and (b) a second transfer module 515 coupled between the exposure platform 500 and an additional (optional) platform 520 to move the substrates there between. In some embodiments, the additional platform 520 may include a plurality of etch modules, a plurality of dry development modules and a transfer module, as shown in FIG. 5. When the additional platform 520 is included, the substrates may pass through the platform 400, the exposure platform 500 and the additional platform 520 in a sequential fashion to perform the deposition steps, exposure step, development step(s) and etch steps disclosed herein. Alternatively, the substrates may be passed back and forth through the platform 400 and the exposure platform 500 to perform the various process steps disclosed herein.

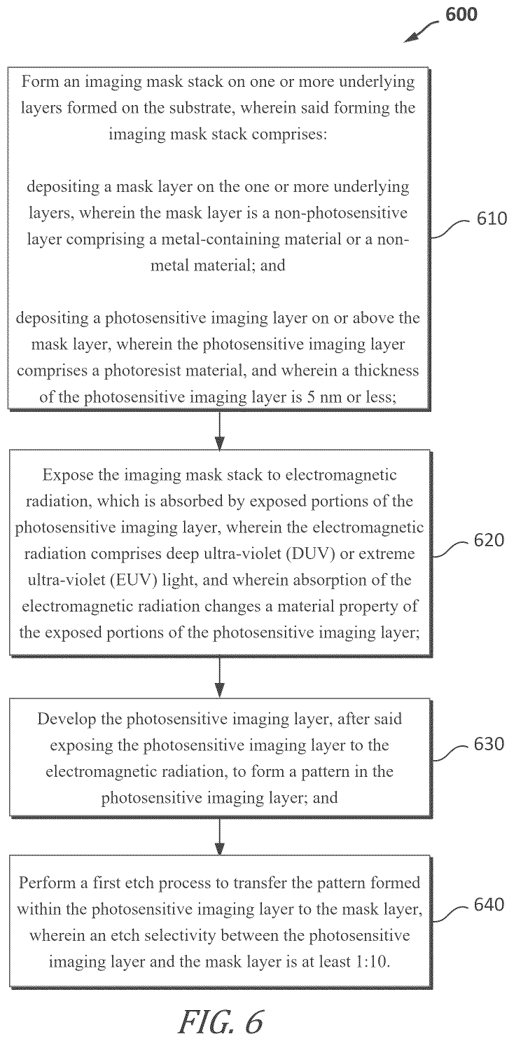

FIG. 6 illustrates one embodiment of a method 600 that utilizes the techniques disclosed herein to lithographically pattern a substrate. It will be recognized that the embodiment of FIG. 6 is merely exemplary and additional methods may utilize the patterning techniques described herein. Further, additional processing steps may be added to the method shown in the FIG. 6 as the steps described are not intended to be exclusive. Moreover, the order of the steps is not limited to the order shown in the figure as different orders may occur and/or various steps may be performed in combination or at the same time.

The method 600 shown in FIG. 6 generally begin by forming an imaging mask stack on one or more underlying layers formed on the substrate (in step 610). The imaging mask stack may be formed in step 610 by depositing a mask layer on the one or more underlying layers and depositing a photosensitive imaging layer on or above the mask layer. The photoresist layer comprises a photoresist material. On the other hand, the mask layer is a non-photosensitive layer comprising a metal-containing material or a non-metal material. As noted above, the photosensitive imaging layer is generally much thinner than the mask layer. For example, the thickness of the photosensitive imaging layer may be 5 nm or less, while the thickness of the mask layer ranges between 10 nm to 50 nm (or more).

The method 600 further includes exposing the imaging mask stack to electromagnetic radiation, which is absorbed by exposed portions of the photosensitive imaging layer (in step 620). The electromagnetic radiation may comprise deep ultra-violet (DUV) or extreme ultra-violet (EUV) light. As noted above, absorption of the electromagnetic radiation changes a material property of the exposed portions of the photosensitive imaging layer. After exposing the photosensitive imaging layer to electromagnetic radiation (in step 620), the method 600 further includes developing the photosensitive imaging layer to form a pattern in the photosensitive imaging layer (in step 630). Once the pattern is formed, the method 600 may perform a first etch process to transfer the pattern formed within the photosensitive imaging layer to the mask layer (in step 640). During the first etch process, an etch selectivity between the photosensitive imaging layer and the mask layer may be at least 1:10 to ensure that the mask layer is etched at a much faster rate than the thin photosensitive imaging layer.

As noted above, the photosensitive imaging layer included within the imaging mask stack may be formed from a wide variety of photoresist materials. In one embodiment, for example, the photosensitive imaging layer may include a DUV photoresist, an EUV photoresist, or a high-NA EUV photoresist. In another embodiment, the photosensitive imaging layer may include a wide variety of metals and metal alloys, such as but not limited to, tin (Sn), antimony (Sb), indium (In), zinc (Zn) and alloys thereof. In further embodiments, the method may further comprise doping the photosensitive imaging layer with a material that differs from a material composition of the photosensitive imaging layer. For example, said doping may include plasma immersion doping, ion implant doping, or gas cluster ion implant doping.

A wide variety of deposition processes can be used in step 620 to deposit the photosensitive imaging layer on or above the mask layer. In one embodiment, the photosensitive imaging layer may be deposited using a gas-phase deposition process, a vapor-phase deposition process, or a liquid-phase deposition process. More specifically, the photosensitive imaging layer may be deposited using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof.

In some embodiments, the imaging mask stack may include one or more additional thin film layers. In one embodiment, the imaging mask stack may be further formed in step 610 by depositing a second mask layer on the photosensitive imaging layer and depositing a second photosensitive imaging layer on the second mask layer. As noted above, the second mask layer and the second photosensitive imaging layer may each have a thickness of 5 nm or less, in some embodiments. The second photosensitive imaging layer may be formed of a photoresist material that is the same or different from the photoresist material used to form the photosensitive imaging layer. Like the mask layer, the second mask layer is a non-photosensitive layer comprising a metal-containing material or a non-metal material. However, unlike the mask layer, the second mask layer may be thin enough (e.g., 5 nm or less) to allow the electromagnetic radiation to pass through the second mask layer to the photosensitive imaging layer underlying the second mask layer.

In another embodiment, the imaging mask stack may be further formed in step 610 by forming a sensitivity enhancement layer between the mask layer and the photosensitive imaging layer. As noted above, the sensitivity enhancement layer may include a material that increases absorption of the electromagnetic radiation within the photosensitive imaging layer. For example, the sensitivity enhancement layer may comprise a material with high electron emission (and/or low work function), which increases the amount of photons absorbed by the photosensitive imaging layer. Alternatively, the sensitivity enhancement layer may comprise a material with high diffusion, which allows dopants or impurities to diffuse into the photosensitive imaging layer to increase the absorption of the electromagnetic radiation in the photosensitive imaging layer. In some embodiments, the sensitivity enhancement layer may include a wide variety of transition metals and transition metal alloys, such as but not limited to, titanium (Ti), hafnium (Hf), zinc (Zn), or alloys thereof.

In some embodiments of the method 600, the steps of forming the imaging mask stack (in step 610), developing the photosensitive imaging layer (in step 630) and performing the first etch process (in step 640) may be performed on a platform comprising a plurality of process modules. FIGS. 4 and 5 illustrate one embodiment of a platform 400 including: (a) a first deposition module for depositing a mask layer on one or more underlying layers formed on the substrate; (b) a second deposition module for depositing a photosensitive imaging layer on or above the mask layer; (c) a third deposition module for depositing a sensitivity enhancement layer between the mask layer and the photosensitive imaging layer; (d) a development module for developing the photosensitive imaging layer, after the photosensitive imaging layer is exposed to the electromagnetic radiation, to form the pattern in the photosensitive imaging layer; (e) an etch module for performing a plurality of etch processes to transfer the pattern formed within the photosensitive imaging layer to the mask layer and the one or more underlying layers, and (f) a transfer module for moving the substrate to between the process modules hosted on the platform. In some embodiments, the plurality of modules may further include: (g) one or more treatment modules for pre-treating the substrate prior to forming the photosensitive imaging layer, or post-treating the substrate following the formation of the photosensitive imagining layer, or both. In some embodiments, the platform may be coupled to an exposure platform, which is configured to expose the substrate to the electromagnetic radiation. FIG. 5 illustrates one embodiment of an integrated platform comprising a platform 400 coupled to an exposure platform 500. In such embodiments, at least one transfer module may be coupled between the platform and the exposure platform to move the substrate there between.

In some embodiments of the method 600, said depositing the photosensitive imaging layer and said depositing the mask layer (in step 610) may each be performed on the platform in a chemical vapor deposition (CVD) module. In some embodiments, said depositing the photosensitive imaging layer and said depositing the mask layer may be performed on the platform in the same process module.

In some embodiments, said developing the photosensitive imaging layer (in step 630) may be performed on the platform in the development module using a wet development process, a dry development process, or a combination of a wet and dry development process. For example, the photosensitive imaging layer may be developed in step 630 using a plasma-free gas-phase development process, a plasma-free vapor-phase development process, a plasma development process, a liquid-phase development process, or any combination of two or more thereof.

In some embodiments, said performing the first etch process (in step 640) may be performed on the platform in the etch module using a wet etch process or a dry etch process. For example, the first etch process may be a plasma-free gas-phase etch process, a plasma-free vapor-phase etch process, a plasma etch process, a liquid-phase etch process, or any combination of two or more thereof. In one example embodiment, the first etch process may be a dry reactive ion etching (RIE) process.

The present disclosure provides various embodiments of imaging mask stacks, platforms for producing an imaging mask stack, and methods for lithographically patterning a substrate using an imaging mask stack as described herein. The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. An imaging mask stack for lithographically patterning a substrate, the imaging mask stack comprising:
a mask layer formed on one or more underlying layers formed on the substrate, wherein the mask layer is a non-photosensitive layer comprising a metal-containing material or a non-metal material; and
a photosensitive imaging layer formed on or above the mask layer, wherein the photosensitive imaging layer comprises a photoresist material that absorbs electromagnetic radiation when the substrate is exposed to light, and wherein a thickness of the photosensitive imaging layer is 5 nm or less.

2. The imaging mask stack of claim 1, wherein the mask layer comprises: (a) the metal-containing material, or (b) a carbon-containing material, a silicon-containing material, an oxide-containing material, a nitride-containing material or a combination thereof, wherein a thickness of the mask layer ranges between 10 nm and 50 nm, and wherein the one or more underlying layers formed beneath the mask layer comprise a target layer to be etched.

3. The imaging mask stack of claim 1, wherein the photosensitive imaging layer comprises a deep ultra-violet (DUV) photoresist, an extreme ultra-violet (EUV) photoresist, or a high-numerical aperture (NA) EUV photoresist.

4. The imaging mask stack of claim 1, wherein the photosensitive imaging layer comprises tin (Sn), antimony (Sb), indium (In), zinc (Zn), or alloys thereof.

5. The imaging mask stack of claim 1, wherein the photosensitive imaging layer is doped with a material that differs from a material composition of the photosensitive imaging layer.

6. The imaging mask stack of claim 1, wherein the photosensitive imaging layer is formed using a gas-phase deposition process, a vapor-phase deposition process, or a liquid-phase deposition process.

7. The imaging mask stack of claim 1, further comprising:
a second mask layer formed on the photosensitive imaging layer, wherein the second mask layer is a non-photosensitive layer comprising the metal-containing material or the non-metal material, and wherein a thickness of the second mask layer is 5 nm or less; and
a second photosensitive imaging layer formed on the second mask layer, wherein the second photosensitive imaging layer comprises the photoresist material, and wherein a thickness of the second photosensitive imaging layer is 5 nm or less.

8. The imaging mask stack of claim 1, further comprising:
a sensitivity enhancement layer formed between the mask layer and the photosensitive imaging layer, wherein the sensitivity enhancement layer comprises a material that increases absorption of the electromagnetic radiation within the photosensitive imaging layer.

9. The imaging mask stack of claim 8, wherein the sensitivity enhancement layer comprises titanium (Ti), hafnium (Hf), zinc (Zn), another transition metal or alloys thereof.

10. A method for lithographically patterning a substrate, comprising:
forming an imaging mask stack on one or more underlying layers formed on the substrate, wherein said forming the imaging mask stack comprises:
depositing a mask layer on the one or more underlying layers, wherein the mask layer is a non-photosensitive layer comprising a metal-containing material or a non-metal material; and
depositing a photosensitive imaging layer on or above the mask layer, wherein the photosensitive imaging layer comprises a photoresist material, and wherein a thickness of the photosensitive imaging layer is 5 nm or less;
exposing the imaging mask stack to electromagnetic radiation, which is absorbed by exposed portions of the photosensitive imaging layer, wherein the electromagnetic radiation comprises deep ultra-violet (DUV) or extreme ultra-violet (EUV) light, and wherein absorption of the electromagnetic radiation changes a material property of the exposed portions of the photosensitive imaging layer;
developing the photosensitive imaging layer, after said exposing the photosensitive imaging layer to the electromagnetic radiation, to form a pattern in the photosensitive imaging layer; and
performing a first etch process to transfer the pattern formed within the photosensitive imaging layer to the mask layer, wherein an etch selectivity between the photosensitive imaging layer and the mask layer is at least 1:10.

11. The method of claim 10, wherein the mask layer comprises: (a) the metal-containing material, or (b) a carbon-containing material, a silicon-containing material, an oxide-containing material, a nitride-containing material or a combination thereof, and wherein a thickness of the mask layer ranges between 10 nm and 50 nm.

12. The method of claim 10, wherein the photosensitive imaging layer comprises a deep ultra-violet (DUV) photoresist, an extreme ultra-violet (EUV) photoresist, or a high-numerical aperture (NA) EUV photoresist.

13. The method of claim 10, wherein the photosensitive imaging layer comprises tin (Sn), antimony (Sb), indium (In), zinc (Zn), or alloys thereof.

14. The method of claim 10, further comprising:
doping the photosensitive imaging layer with a material that differs from a material composition of the photosensitive imaging layer, wherein said doping comprises plasma immersion doping, ion implant doping, or gas cluster ion implant doping.

15. The method of claim 10, wherein the photosensitive imaging layer is deposited using a spin-on deposition process, a chemical vapor deposition (CVD) process, an atomic layer deposition (ALD) process, an atomic beam deposition (ABD) process, a molecular beam deposition (MBD) process, a physical vapor deposition (PVD) process, or any combination thereof.

16. The method of claim 10, wherein said forming the imaging mask stack further comprises:
depositing a second mask layer on the photosensitive imaging layer, wherein the second mask layer is a non-photosensitive layer comprising the metal-containing material or the non-metal material, and wherein a thickness of the second mask layer is 5 nm or less; and
depositing a second photosensitive imaging layer on the second mask layer, wherein the second photosensitive imaging layer comprises the photoresist material, and wherein a thickness of the second photosensitive imaging layer is 5 nm or less.

17. The method of claim 10, wherein said forming the imaging mask stack further comprises:
forming a sensitivity enhancement layer between the mask layer and the photosensitive imaging layer, wherein the sensitivity enhancement layer comprises a material that increases absorption of the electromagnetic radiation within the photosensitive imaging layer.

18. The method of claim 17, wherein the sensitivity enhancement layer comprises titanium (Ti), hafnium (Hf), zinc (Zn), another transition metal or alloys thereof.

19. The method of claim 10, wherein said forming the imaging mask stack, said developing the photosensitive imaging layer and said performing the first etch process are performed on a platform comprising a plurality of process modules.

20. The method of claim 19, wherein said depositing the photosensitive imaging layer and said depositing the mask layer are each performed on the platform in a chemical vapor deposition (CVD) module.

21. The method of claim 19, wherein said depositing the photosensitive imaging layer and said depositing the mask layer are performed on the platform in the same process module.

22. The method of claim 19, wherein said developing the photosensitive imaging layer is performed on the platform in a development module using a wet development process, a dry development process, or a combination of a wet and dry development process.

23. The method of claim 19, wherein said performing the first etch process is performed on the platform in an etch module using a wet etch process or a dry etch process.
